(19) United States
(12) Patent Application Publication
(10) Pub. No.: US 2026/0107635 A1
(43) Pub. Date: Apr. 16, 2026

(54) DISPLAY DEVICE AND METHOD OF MANUFACTURING THE SAME

(71) Applicant: Samsung Display Co., Ltd., Yongin-si (KR)

(72) Inventors: JUNGHO CHOI, Yongin-si (KR); YOUNGKUK KIM, Yongin-si (KR); SEOKHWAN BANG, Yongin-si (KR); JOO-HEE LEE, Yongin-si (KR)

(73) Assignee: Samsung Display Co., Ltd., Yongin-si (KR)

(21) Appl. No.: 19/262,555

(22) Filed: Jul. 8, 2025

(30) Foreign Application Priority Data
Oct. 11, 2024 (KR) 10-2024-0138732

(51) Int. Cl. H10K 59/121; H10K 59/12; H10K 59/122; H10K 59/123; H10K 59/124; H10K 59/80; H10K 102/10

(52) U.S. Cl. CPC H10K 59/1213; H10K 59/1201; H10K 59/122; H10K 59/123; H10K 59/124; H10K 59/80524; H10K 59/878; H10K 2102/101

(57) ABSTRACT

Provided are a display device and a method of manufacturing the same. The display device includes a pixel circuit including at least one thin-film transistor, an organic light-emitting diode electrically connected to the pixel circuit, and an insulating layer defining a pixel area for the organic light-emitting diode. The organic light-emitting diode includes a pixel electrode electrically connected to the pixel circuit, an opposite electrode opposite at least the pixel electrode, and an organic layer disposed between at least the pixel electrode and the opposite electrode and including at least an emission layer. The pixel electrode includes a first pixel electrode in contact with the organic layer, a reflective layer opposite the first pixel electrode and that reflects light from the emission layer, and a protective layer disposed between the first pixel electrode and the reflective layer and that protects the reflective layer.

### CROSS-REFERENCE TO RELATED APPLICATION(S)

This application claims priority to and benefits of Korean Patent Application No. 10-2024-0138732 under 35 U.S.C. § 119, filed on Oct. 11, 2024, in the Korean Intellectual Property Office, the entire contents of which are incorporated herein by reference.

### BACKGROUND

### 1. Technical Field

One or more embodiments relate to a display device and a method of manufacturing the display device.

### 2. Description of the Related Art

A flat panel display device, such as an organic light-emitting display or a liquid crystal display, is manufactured on a substrate in which at least one thin-film transistor (TFT), a capacitor, and a pattern including a wire connecting the at least TFT to the capacitor are formed for driving. The TFT includes an active layer including a channel region, a source region, and a drain region, and a gate electrode electrically insulated from the active layer by a gate insulating layer.

In general, the active layer of the TFT includes a semiconductor material, such as amorphous silicon or poly-silicon. In case that the active layer includes amorphous silicon, the mobility is low, making it difficult to implement a high-speed driving circuit. In case that the active layer includes poly-silicon, the mobility is high, but the threshold voltage may be non-uniform, and a separate compensation circuit may be required. Furthermore, because a conventional TFT manufacturing method using low temperature poly-silicon (LTPS) includes an expensive process, such as laser heat treatment, facility investment and management costs are high and it is difficult to apply to large-area substrates. In this regard, studies have recently been conducted to use oxide semiconductors as active layers.

### SUMMARY

Characteristics of thin-film transistors (TFTs) using oxide semiconductors can be changed when external light penetrates into an active layer. As one of the methods of blocking external light, a black pixel defining layer may be used, or a pixel electrode including a reflective layer may be used.

For example, voids may occur in the reflective layer as an unrefined material of the pixel defining layer penetrates into the reflective layer of the pixel electrode during a manufacturing process.

One or more embodiments may provide a display device and a method of manufacturing the display device, in which damage to a reflective layer included in a pixel electrode during a manufacturing process, is minimized. However, this is only an example and the scope of the disclosure is not limited thereby.

According to one or more embodiments, a display device includes a pixel circuit including at least one thin-film transistor, an organic light-emitting diode electrically connected to the pixel circuit, and an insulating layer defining a pixel area for the organic light-emitting diode, wherein the organic light-emitting diode includes a pixel electrode electrically connected to the pixel circuit, an opposite electrode opposite at least the pixel electrode, and an organic layer disposed between at least the pixel electrode and the opposite electrode and including at least an emission layer, and The pixel electrode includes a first pixel electrode in contact with the organic layer, a reflective layer opposite the first pixel electrode and that reflects light from the emission layer, and a protective layer disposed between the first pixel electrode and the reflective layer and that protects the reflective layer.

The protective layer may include a transparent conductive layer.

The transparent conductive layer may include an amorphous layer.

The transparent conductive layer may include a stack of a first protective layer including a same material as a material of the first pixel electrode and a second protective layer formed as an amorphous layer.

Each of the first pixel electrode and the protective layer may include a transparent conductive layer including an oxygen component, and an amount of the oxygen component of the protective layer may be smaller than an amount of the oxygen component of the first pixel electrode.

Each of the first pixel electrode and the protective layer may include a transparent conductive layer including a tin component, and an amount of the tin component of the protective layer may be larger than an amount of the tin component of the first pixel electrode.

A stack of the first pixel electrode and the protective layer may be stacked in a plurality of layers.

The display device may further include a second pixel electrode electrically connected to the pixel circuit to form an ohmic contact, wherein the reflective layer may be disposed between the second pixel electrode and the protective layer.

According to one or more embodiments, a method of manufacturing a display device includes preparing a circuit substrate including a pixel circuit including at least one thin-film transistor, forming, on the circuit substrate, an organic light-emitting diode electrically connected to the pixel circuit, and forming, on the circuit substrate, an insulating layer defining a pixel area for the organic light-emitting diode, wherein the forming of the organic light-emitting diode includes forming a pixel electrode electrically connected to the pixel circuit, forming, on the pixel electrode, an organic layer including at least an emission layer, and forming an opposite electrode on at least the organic layer, and the forming of the pixel electrode includes forming a reflective layer that reflects light from the emission layer, forming, on the reflective layer, a protective layer that protects the reflective layer, and forming, on the protective layer, a first pixel electrode in contact with the organic layer.

The forming of the protective layer may include forming a transparent conductive layer.

The transparent conductive layer may include an amorphous layer.

The method may further include forming the transparent conductive layer, forming a first protective layer including a same material as a material of the first pixel electrode, and forming, on the first protective layer, a second protective layer formed as an amorphous layer.

Each of the first pixel electrode and the protective layer may include a transparent conductive layer including an oxygen component, and the forming of the protective layer may include forming the transparent conductive layer and performing oxygen plasma treatment on at least a portion of the transparent conductive layer.

Each of the first pixel electrode and the protective layer may include a transparent conductive layer including a tin component, and the forming of the protective layer may be performed so that an amount of the tin component of the protective layer may be smaller than an amount of the tin component of the first pixel electrode.

The forming of the protective layer may include forming a first-1 protective layer and forming a first-2 protective layer, wherein the forming of the first pixel electrode may include forming a first-1 pixel electrode between the first-1 protective layer and the first-2 protective layer and forming a first-2 pixel electrode on the first-2 protective layer.

The method may further include forming a second pixel electrode electrically connected to the pixel circuit to form an ohmic contact, wherein the forming of the reflective layer may include forming the reflective layer between the second pixel electrode and the protective layer.

According to one or more embodiments, an electronic device may include: a display device including: a pixel circuit comprising at least one thin-film transistor; an organic light-emitting diode electrically connected to the pixel circuit; and an insulating layer defining a pixel area, wherein the organic light-emitting diode may include: a pixel electrode electrically connected to the pixel circuit; an opposite electrode opposite at least the pixel electrode; and an organic layer disposed between at least the pixel electrode and the opposite electrode and comprising at least an emission layer, the pixel electrode may include: a first pixel electrode in contact with the organic layer; a reflective layer opposite the first pixel electrode and that reflects light from the emission layer; and a protective layer disposed between the first pixel electrode and the reflective layer and that protects the reflective layer.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

### BRIEF DESCRIPTION OF THE DRAWINGS

FIG. 1 is a schematic perspective view of a display device according to an embodiment;

FIGS. 2A and 2B are schematic cross-sectional views of display devices according to an embodiment, respectively;

FIGS. 3A and 3B are schematic diagrams of an equivalent circuit of a pixel according to an embodiment, respectively;

FIG. 4 is a schematic cross-sectional view illustrating a pixel according to an embodiment;

FIG. 5 is a schematic cross-sectional view illustrating region A of FIG. 4 according to an embodiment;

FIG. 6 is a graph showing an X-ray diffraction (XRD) difference of indium tin oxide (ITO) according to an oxygen plasma treatment time;

FIG. 7 is a graph showing an XRD difference of ITO according to a concentration ratio of tin;

FIG. 8 is a schematic cross-sectional view illustrating region A of FIG. 4 according to another embodiment;

FIG. 9 is a schematic cross-sectional view illustrating region A of FIG. 4 according to another embodiment; and

FIGS. 10 and 11 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction X, the axis of the second direction Y, and the axis of the third direction Z are not limited to three axes of a rectangular coordinate system, such as the X, Y, and Z-axes, and may be interpreted in a broader sense. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

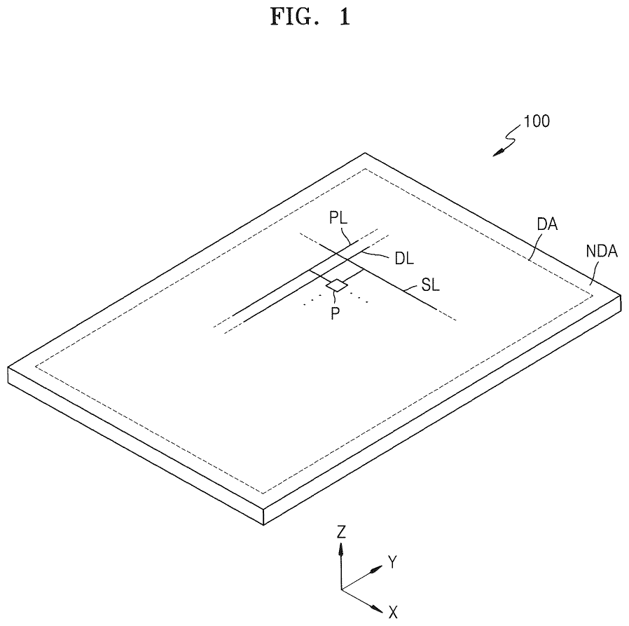

FIG. 1 is a schematic perspective view of a display device 100 according to an embodiment.

Referring to FIG. 1, the display device 100 may include a display area DA and a non-display area NDA extending outward from the display area DA. The display device 100 may display an image in the display area DA. Examples of the display device 100 may include a liquid crystal display, an electrophoretic display, an organic light-emitting display, an inorganic light-emitting display, a quantum dot light-emitting display, a field emission display, a surface-conduction electron-emitter display, a plasma display, and a cathode ray display.

Referring to FIG. 1, the display device 100 may include pixels P disposed in the display area DA. Each pixel P may be electrically connected to a scan line SL extending in a first direction X, a data line DL extending in a second direction Y, and a driving voltage line PL extending in the second direction Y. A third direction Z may be perpendicular to the plane defined by the first direction X and the second direction Y.

Some of the pixels P may emit red light, green light, blue light, or white light and may include, for example, an organic light-emitting diode. In some embodiments, each of the pixels P may include a pixel circuit including a combination of elements, such as a TFT and a capacitor.

Hereinafter, an organic light-emitting display is described as an example of the display device 100 according to an embodiment. However, the display device of the disclosure is not limited thereto, and other types of display device may also be used.

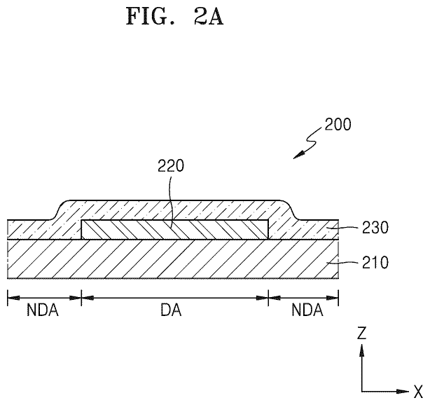

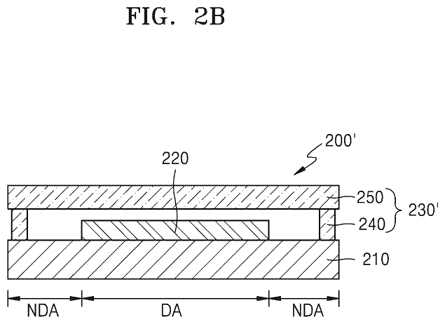

FIGS. 2A and 2B are schematic cross-sectional views of display devices 200 and 200′ according to an embodiment, respectively.

Referring to FIG. 2A, the display device 200 may include a display element layer 220 on a first substrate 210 and an encapsulation member 230 which covers the display element layer 220.

In other embodiments, the first substrate 210 may include glass.

In other embodiments, the first substrate 210 may include polymer resin, such as polyether sulfone, polyacrylate, polyether imide, polyethylene naphthalate, polyethylene terephthalate, polyphenylene sulfide, polyarylate, polyimide, polycarbonate, or cellulose acetate propionate.

In other embodiments, the first substrate 210 may include a flexible metal material.

In other embodiments, the first substrate 210 may have a single-layer structure or multilayer structure of the material described above. The first substrate 210 may further include an inorganic layer and/or an organic layer.

In other embodiments, the first substrate 210 may be flexible, rollable, or bendable.

The display element layer 220 may include the pixels P. Each of the pixels P may include an organic light-emitting diode and a pixel circuit electrically connected to the organic light-emitting diode. The pixel circuit may include thin-film transistors (TFTs), a storage capacitor, conductive lines connected to the TFTs and the storage capacitor, or the like, and may include insulating layers.

The encapsulation member 230 may protect the display element layer 220 from external foreign materials, such as moisture. The encapsulation member 230 may be a thin-film encapsulation layer including at least one inorganic encapsulation layer and/or at least one organic encapsulation layer. The at least one inorganic encapsulation layer may include a silicon oxide layer, a silicon nitride layer or/and a silicon oxynitride layer, a titanium oxide layer, an aluminum oxide layer, or the like, but the disclosure is not limited thereto. The at least one organic encapsulation layer may include an acrylic-based organic material, but the disclosure is not limited thereto.

The encapsulation member 230 of FIG. 2A may include inorganic encapsulation layers and organic encapsulation layers disposed between the inorganic encapsulation layers. The stacking order of the inorganic encapsulation layers and the organic encapsulation layers may be variously changed. Although FIG. 2A illustrates that the encapsulation member 230 is a thin-film encapsulation layer, the disclosure is not limited thereto.

Referring to FIG. 2B, the display device 200′ may include an encapsulation member 230′ including a sealing portion 240 and a second substrate 250. A first substrate 210 of FIG. 2B may include the polymer resin described above, or may include glass or metal.

The second substrate 250 may be disposed to face the first substrate 210, and the sealing portion 240 may be disposed between the first substrate 210 and the second substrate 250. The sealing portion 240 may surround a display area DA. An internal space defined by the first substrate 210, the second substrate 250, and the sealing portion 240 may be separated from the outside and may prevent penetration of moisture or impurities. The second substrate 250 may include the polymer resin, metal, or glass described above and the sealing portion 240 may use frit or epoxy.

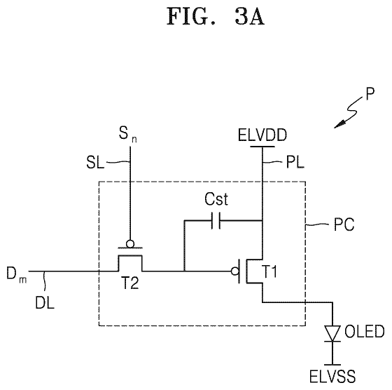

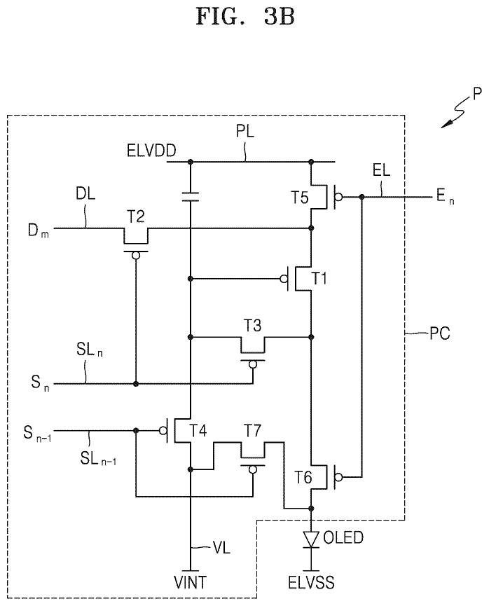

FIGS. 3A and 3B are schematic diagrams of an equivalent circuit of a pixel according to an embodiment, respectively.

Referring to FIG. 3A, each of the pixels P may include a pixel circuit PC connected to the scan line SL, the data line DL, and the driving voltage line PL, and an organic light-emitting diode OLED connected to the pixel circuit PC. The pixel circuit PC may include a driving TFT T1, a switching TFT T2, and a storage capacitor Cst.

The switching TFT T2 may transmit, to the driving TFT T1, a data signal Dₘ input through the data line DL in response to a scan signal Sₙ input through the scan line SL.

The storage capacitor Cst may be connected to the switching TFT T2 and the driving voltage line PL and may store a voltage corresponding to a difference between a voltage received from the switching TFT T2 and a first power supply voltage (or a driving voltage) ELVDD supplied to the driving voltage line PL.

The driving TFT T1 may be connected to the driving voltage line PL and the storage capacitor Cst and may control a driving current flowing from the driving voltage line PL to the organic light-emitting diode OLED according to a voltage value stored in the storage capacitor Cst. The organic light-emitting diode OLED may emit light with a certain luminance according to the driving current.

Although FIG. 3A illustrates that the pixel circuit PC includes two TFTs and one storage capacitor, the disclosure is not limited thereto. Although FIG. 3A illustrates that the TFTs are p-type TFTs, the disclosure is not necessarily limited thereto, and at least one TFT may be an n-type TFT. In other embodiments, the switching TFT T2 may be designed as an n-type TFT and the driving TFT T1 may be designed as a p-type TFT.

Referring to FIG. 3B, a pixel circuit PC may include a driving TFT T1, a switching TFT T2, a compensation TFT T3, a first initialization TFT T4, a first emission control TFT T5, a second emission control TFT T6, and a second initialization TFT T7.

Although FIG. 3B illustrates a case where signal lines SLₙ, SLₙ₋₁, EL, and DL, an initialization voltage line VL, and the driving voltage line PL are provided for each pixel P, the disclosure is not limited thereto. In other embodiments, the initialization voltage line VL and/or at least one of the signal lines SLₙ, SLₙ₋₁, EL, and DL may be shared by neighboring pixels.

An electrode of the driving TFT T1 may be electrically connected to an organic light-emitting diode OLED via the second emission control TFT T6. The driving TFT T1 may receive a data signal Dₘ according to the switching operation of the switching TFT T2 and supply a driving current to the organic light-emitting diode OLED.

A gate electrode of the switching TFT T2 may be connected to a first scan line SLₙ and a first electrode of the switching TFT T2 may be connected to the data line DL. A second electrode of the switching TFT T2 may be connected to a first electrode of the driving TFT T1 and connected to the driving voltage line PL via the first emission control TFT T5.

The switching TFT T2 may be turned on in response to a first scan signal Sₙ received through the first scan line SLₙ and perform a switching operation to transmit the data signal Dₘ from the data line DL to the first electrode of the driving TFT T1.

A gate electrode of the compensation TFT T3 may be connected to the first scan line SLₙ. A first electrode of the compensation TFT T3 may be connected to a second electrode of the driving TFT T1 and connected to a pixel electrode of the organic light-emitting diode OLED via the second emission control TFT T6. A second electrode of the compensation TFT T3 may be connected to an electrode of a storage capacitor Cst, a first electrode of the first initialization TFT T4, and a gate electrode of the driving TFT T1. The compensation TFT T3 may be turned on in response to the first scan signal Sₙ received through the first scan line SLₙ and connect the gate electrode of the driving TFT T1 to the second electrode of the driving TFT T1 so that the driving TFT T1 may be diode-connected.

A gate electrode of the first initialization TFT T4 may be connected to a second scan line (e.g., a previous scan line) SLₙ₋₁. A second electrode of the first initialization TFT T4 may be connected to the initialization voltage line VL. A first electrode of the first initialization TFT T4 may be connected to the electrode of the storage capacitor Cst, the second electrode of the compensation TFT T3, and the gate electrode of the driving TFT T1. The first initialization TFT T4 may be turned on in response to a second scan signal Sₙ₋₁ received through the second scan line SLₙ₋₁ and perform an initialization operation to transmit an initialization voltage VINT to the gate electrode of the driving TFT T1 so as to initialize the voltage of the gate electrode of the driving TFT T1.

A gate electrode of the first emission control TFT T5 may be connected to an emission control line EL. A first electrode of the first emission control TFT T5 may be connected to the driving voltage line PL. A second electrode of the first emission control TFT T5 may be connected to the first electrode of the driving TFT T1 and the second electrode of the switching TFT T2.

A gate electrode of the second emission control TFT T6 may be connected to the emission control line EL. A first electrode of the second emission control TFT T6 may be connected to the second electrode of the driving TFT T1 and the first electrode of the compensation TFT T3. A second electrode of the second emission control TFT T6 may be electrically connected to the pixel electrode of the organic light-emitting diode OLED. The first emission control TFT T5 and the second emission control TFT T6 may be simultaneously turned on in response to an emission control signal Eₙ received through the emission control line EL so that a first power supply voltage ELVDD may be transmitted to the organic light-emitting diode OLED and a driving current may flow to the organic light-emitting diode OLED.

A gate electrode of the second initialization TFT T7 may be connected to the second scan line SLₙ₋₁. A first electrode of the second initialization TFT T7 may be connected to the pixel electrode of the organic light-emitting diode OLED. A second electrode of the second initialization TFT T7 may be connected to the initialization voltage line VL. The second initialization TFT T7 may be turned on in response to the second scan signal Sₙ₋₁ received through the second scan line SLₙ₋₁ and initialize the pixel electrode of the organic light-emitting diode OLED.

Although FIG. 3B illustrates that the first initialization TFT T4 and the second initialization TFT T7 are connected to the second scan line SLₙ₋₁, the disclosure is not limited thereto. In other embodiments, the first initialization TFT T4 may be connected to the second scan line SLₙ₋₁, which is the previous scan line, and driven in response to the second scan signal Sₙ₋₁, and the second initialization TFT T7 may be connected to a separate signal line (e.g., a next scan line) and driven in response to a signal transmitted to the corresponding scan line.

Another electrode of the storage capacitor Cst may be connected to the driving voltage line PL. The electrode of the storage capacitor Cst may be connected to the gate electrode of the driving TFT T1, the second electrode of the compensation TFT T3, and the first electrode of the first initialization TFT T4.

An opposite electrode (e.g., a cathode) of the organic light-emitting diode OLED may receive a second power supply voltage (e.g., a common power supply voltage) ELVSS. The organic light-emitting diode OLED may receive the driving current from the driving TFT T1 and externally emit light.

Although FIG. 3B illustrates that the TFTs are p-type TFTs, the disclosure is not necessarily limited thereto, and at least one TFT may be an n-type TFT.

In other embodiments, the switching-type TFTs T3 and T4 which are sensitive to current leakage may be designed as n-type TFTs and the remaining TFTs T1, T2, and T5 to T7 may be designed as p-type TFTs. In other embodiments, the n-type TFTs may be TFTs using an oxide active layer capable of reducing current leakage in an off state, and the p-type TFTs may be TFTs using a poly-silicon-based active layer having a good driving speed and stable bias stress.

The pixel circuit PC is not limited to the number and circuit design of the TFTs and the storage capacitor described with reference to FIGS. 3A and 3B, and the number and circuit design of the TFTs and the storage capacitor may be variously modified.

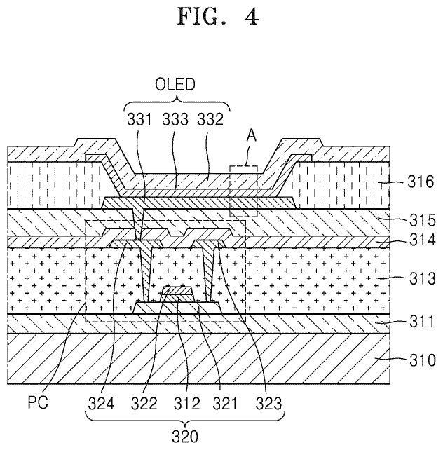

FIG. 4 is a schematic cross-sectional view illustrating the pixel of the display device described above, according to an embodiment.

Referring to FIG. 4, a pixel circuit PC including a TFT 320 may be formed on a first substrate 310. An insulating layer 315 may be formed to cover the pixel circuit PC. An organic light-emitting diode OLED electrically connected to the pixel circuit PC may be formed on the insulating layer 315. The TFT 320 in FIG. 4 may correspond to the driving TFT T1 described with reference to FIG. 3A or the second emission control TFT T6 described with reference to FIG. 3B.

A buffer layer 311 provided (or formed) as an insulating layer may be formed on the first substrate 310. An active layer 321 of the TFT 320 may be formed on the buffer layer 311.

The TFT 320 may include a semiconductor active layer 321, a gate electrode 322, a first electrode 323, and a second electrode 324. The gate electrode 322 may overlap a channel region with a gate insulating layer 312. The gate insulating layer 312 may be disposed between the gate electrode 322 and at least the channel region of the active layer 321. The first electrode 323 and the second electrode 324 may be respectively connected to a source region and a drain region of the active layer 321.

The active layer 321 may include poly-silicon or amorphous silicon.

In other embodiments, the active layer 321 may include an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the active layer 321 may include an oxide semiconductor, such as indium gallium zinc oxide (IGZO), zinc tin oxide (ZTO), or zinc indium oxide (ZIO). In other embodiments, the active layer 321 may include IGZO. In case that the active layer 321 includes an oxide semiconductor, current leakage in an off state may be reduced.

The gate insulating layer 312 may be a single layer or multiple layers including silicon oxide (SiOₓ) or silicon nitride (SiNₓ). The gate electrode 322 may be a single layer or multiple layers including at least one metal selected from aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), and copper (Cu).

In case that the active layer 321 includes a silicon-based material, each of the source region and/or the drain region may be doped with impurities. In other embodiments, in case that the active layer 321 includes an oxide semiconductor, the source region and the drain region may be made conductive by plasma or the like to improve conductivity.

After the gate electrode 322 is formed, the gate electrode 322 may be used as a self-alignment mask to dope impurities into or perform plasma treatment or the like on portions of the active layer 321 which do not overlap the gate electrode 322. Accordingly, the conductivity of the source region and the drain region may be improved.

An interlayer insulating layer 313 may be formed on the buffer layer 311 to cover the active layer 321, the gate electrode 322, and the gate insulating layer 312. Holes which expose the source region and the drain region of the active layer 321 may be formed through an etching process. The interlayer insulating layer 313 may be a single layer or multiple layers including an inorganic material, such as silicon oxide (SiOₓ), silicon nitride (SiNₓ), and/or aluminum oxide (Al₂O₃).

A first electrode 323 and a second electrode 324 may be formed on the interlayer insulating layer 313. The first electrode 323 and the second electrode 324 may be respectively electrically connected to the source region and the drain region of the active layer 321 through the holes formed in the interlayer insulating layer 313.

A passivation layer 314 may be formed on the interlayer insulating layer 313. A planarization layer 315 may be formed on the passivation layer 314. The passivation layer 314 may be a single layer or multiple layers including an inorganic material, such as silicon oxide (SiOₓ), silicon nitride (SiNₓ), and/or aluminum oxide (Al₂O₃). The planarization layer 315 may include an organic material including general-purpose polymer, such as poly(methyl methacrylate) (PMMA) or polystyrene (PS), polymer derivatives having a phenolic group, acrylic-based polymer, imide-based polymer, aryl ether-based polymer, amide-based polymer, fluorine-based polymer, p-xylene-based polymer, vinyl alcohol-based polymer, and any blend thereof, but the disclosure is not limited thereto. In an embodiment, a stacked structure in which the passivation layer 314 and the planarization layer 315 are sequentially formed on the interlayer insulating layer 313 is illustrated, but the disclosure is not necessarily limited thereto, and only one of the passivation layer 314 and the planarization layer 315 may be used. In the following embodiment, a stacked structure in which the passivation layer 314 and the planarization layer 315 are sequentially formed is described.

Holes which expose the second electrode 324 may be formed in the passivation layer 314 and the planarization layer 315 through an etching process.

An organic light-emitting diode OLED may be formed on the planarization layer 315.

The organic light-emitting diode OLED may include a pixel electrode 331, an organic layer 333, and an opposite electrode 332. The pixel electrode 331 may be disposed on the planarization layer 315, may be electrically connected to the TFT 320, and may be exposed to the outside while the edge portion of the pixel electrode 331 is covered by a pixel defining layer 316. The organic layer 333 may be disposed to correspond to (or overlap) the pixel electrode 331 exposed through the pixel defining layer 316. The opposite electrode 332 may be formed on the organic layer 333 as a common electrode which covers the organic layer 333 and the pixel defining layer 316.

The pixel defining layer 316 may be disposed on the pixel electrode 331. The pixel defining layer 316 may define a pixel by having an opening corresponding to (or overlapping) each of the pixels P, e.g., an opening which exposes a portion of the pixel electrode 331. For example, the pixel defining layer 316 may prevent an electric arc or the like from occurring between the edge portion of the pixel electrode 331 and the opposite electrode 332 by increasing the distance between the edge portion of the pixel electrode 331 and the opposite electrode 332.

The pixel defining layer 316 may include an organic insulating material and an inorganic insulating material, or may include only an organic insulating material or only an inorganic insulating material.

The pixel defining layer 316 may include impurity components, for example, reactive components, during the process or due to material limitations. According to an embodiment, the reactive components may include unrefined chlorine (Cl).

In other embodiments, the active layer of one of the TFTs included in the pixel circuit PC may include an oxide semiconductor, for example, IGZO. Thus, current leakage in an off state may be reduced.

However, the oxide semiconductor may be sensitive to external light, which changes characteristics of the display device.

As one of the methods of blocking external light, the pixel defining layer 316 may be made of a light-opaque material. For example, the pixel defining layer 316 may use a material including black pigment. In case that the black pixel defining layer 316 including black pigment is used, the reliability of the display device may be improved. For example, a Vth fluctuation range may be reduced.

The black pixel defining layer 316 including black pigment may be applied in case that the active layer is a silicon-based semiconductor. The use of the black pixel defining layer may further increase the contrast of the pixel.

The black pixel defining layer 316 including black pigment may require chlorine (Cl) components so as to synthesize a binder. In case that a cardo-type binder is used as the binder, Cl components are required. The inclusion of Cl— may be inevitable for an epoxy reaction of a cardo-type binder.

However, in case that the Cl components are refined by an adsorption filter, a refinement effect is limited. Table 1 below shows a change in Cl— ions (unit: ppm) in a cardo-type binder according to the number of times of refinements and indicates that the refinement effect does not improve after two or more refinements.

TABLE 1

| Analysis of cardo- | Before | | | | |
|---|---|---|---|---|---|
| type binder | refinement | 1 time | 2 times | 3 times | 4 times |
| Cl | 699 | 501 | 451 | 442 | 449 |

As described above, impurity components, such as Cl components, in the pixel defining layer 316 may damage the pixel electrode 331. According to an embodiment, the impurity components may react with metal components of the pixel electrode 331 to form voids in the pixel electrode 331.

To solve the above problem, the pixel electrode 331 may include a protective layer.

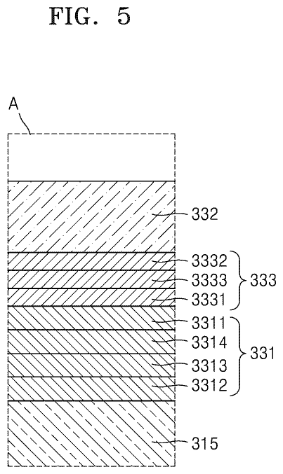

FIG. 5 is an enlarged schematic cross-sectional view of region A of FIG. 4 and illustrates a specific cross-section of the organic light-emitting diode according to an embodiment.

The pixel electrode 331 may be formed on the planarization layer 315. The pixel defining layer 316 may be formed to cover the pixel electrode 331. An opening may be drilled in the pixel defining layer 316 to expose the pixel electrode 331.

The organic layer 333 and the opposite electrode 332 may be stacked above the exposed pixel electrode 331.

The organic layer 333 may include an emission layer 3333. The emission layer 3333 may include an organic light-emitting material which emits red light, green light, blue light, or white light for each pixel. The organic light-emitting material may include a low molecular weight organic material or a high molecular weight organic material.

The emission layer 3333 may include various organic materials including copper phthalocyanine, N,N′-di(naphthalene-1-yl)-N,N′-diphenyl-benzidine, tris-8-hydroxyquinoline aluminum (Alq3), or the like. These layers may be formed by vacuum deposition.

The organic light-emitting diode OLED may further include functional layers disposed adjacent to the emission layer 3333. For example, a first intermediate layer 3331 may be disposed between the pixel electrode 331 and the emission layer 3333, and a second intermediate layer 3332 may be disposed between the emission layer 3333 and the opposite electrode 332. The first intermediate layer 3331 may include a hole injection layer (HIL) and/or a hole transport layer (HTL), and the second intermediate layer 3332 may include an electron transport layer (ETL) and/or an electron injection layer (EIL). The first intermediate layer 3331 and the second intermediate layer 3332 may be disposed to correspond to (or overlap) the pixel electrode 331 and may extend along the plane direction to correspond to (or overlap) the pixel defining layer 316.

In case that the organic layer 333 includes a polymer material, the intermediate layer 513 may usually have a structure including an HTL and an emission layer. For example, the HTL may include poly(3,4-ethylenedioxythiophene (PEDOT) and the emission layer may include a polymer material, such as poly-phenylenevinylene (PPV) and polyfluorene.

The structure of the organic layer 333 is not limited to those described above and the organic layer 333 may have other structures. For example, at least one of the layers constituting the organic layer 333 may be integrally formed across the pixel electrodes 331. For example, the organic layer 333 may include a layer patterned to correspond to (or to overlap) each of the pixel electrodes 331.

The opposite electrode 332 may be disposed above the display area DA and may cover the display area DA. For example, the opposite electrode 332 may be integrally formed to cover the pixels P.

According to an embodiment, because light from the emission layer 3333 is emitted toward the opposite electrode 332, a top emission structure may be implemented. Accordingly, the opposite electrode 332 may be provided (or formed) as a transparent conductive layer or a semitransparent conductive layer. According to an embodiment, the opposite electrode 332 may include a metal thin-film having a low work function and including Li, Ca, LiF/Ca, LiF/Al, Al, Ag, Mg, and any compound thereof. In some embodiments, a transparent conductive oxide (TCO) layer, such as ITO, indium zinc oxide (IZO), zinc oxide (ZnO), or indium oxide (In₂O₃), may be further disposed on the metal thin-film.

The opposite electrode 332 may extend not only to the display area DA but also to the non-display area NDA outside the display area DA illustrated in FIG. 1.

Because the opposite electrode 332 is formed to cover the entire display area DA, the resistance of the opposite electrode 332 may be relatively high, compared to other wires or electrodes. IR drop and luminance deviation may occur when the resistance of the opposite electrode 332 is excessively high. Accordingly, IR drop of the opposite electrode 332 may be reduced by further providing an auxiliary electrode electrically connected to the opposite electrode 332 in the non-display area NDA and/or the display area DA.

The pixel electrode 331 formed on the planarization layer 315 may include a first pixel electrode 3311, a reflective layer 3313, and a protective layer 3314.

The first pixel electrode 3311 may be provided (or formed) as a transparent conductive layer or a semitransparent conductive layer and may include, for example, at least one selected from ITO, IZO, ZnO, In₂O₃, indium gallium oxide (IGO), and aluminum zinc oxide (AZO).

According to an embodiment, the first pixel electrode 3311 may be in contact with the organic layer 333 and may use ITO. In case that ITO is used, the work function gap of the organic layer 333, e.g., the first intermediate layer 3331, e.g., the HTL, and the first pixel electrode 3311 may be appropriately matched to prevent the driving voltage from increasing.

The reflective layer 3313 may be disposed from the first pixel electrode 3311 in a direction away from the organic layer 333.

The reflective layer 3313 may include a reflective material including Ag, Mg, Al, Pt, Pd, Au, Ni, Nd, Ir, Cr, or any compound thereof. According to other embodiments, the reflective layer 3313 may include Ag or an Ag compound.

The reflective layer 3313 may reflect light from the emission layer 3333 of the organic layer 333 toward the opposite electrode 332, and thus, top emission may be implemented.

According to an embodiment, the protective layer 3314 which protects the reflective layer 3313 may be further included between the first pixel electrode 3311 and the reflective layer 3313.

As described above, the protective layer 3314 may protect the reflective layer 3313 from unrefined impurity elements included in the pixel defining layer 316 and may protect the reflective layer 3313 from penetration of external gas.

As described above, in case that the pixel defining layer 316 includes unrefined chlorine (Cl) elements, crystallization occurs on the first pixel electrode 3311 during a process of curing the pixel defining layer 316. Accordingly, chlorine (Cl) components included in the pixel defining layer 316 may penetrate into the reflective layer 3313 between crystallized pinholes. For example, a metal material of the reflective layer 3313 may react with Cl— ions to form a compound of, for example, AgCl. This may cause a defect in the form of a void within the reflective layer 3313.

The protective layer 3314 may prevent pixel defects from occurring by protecting the reflective layer 3313 from the outside, for example, external elements which penetrate from the pixel defining layer 316 into the reflective layer 3313. The protective layer 3314 may also prevent the metal component of the reflective layer 3313 from being oxidized due to penetration of external oxygen or moisture.

In other embodiments, the protective layer 3314 may be provided (or formed) as a transparent conductive layer or a semitransparent conductive layer. Because the protective layer 3314 is provided (or formed) as a transparent conductive layer or a semitransparent conductive layer, a reduction in reflectivity of the reflective layer 3313 for the protective layer 3314, may be prevented.

In other embodiments, the protective layer 3314 may be provided (or formed) as a transparent conductive layer or a semitransparent conductive layer having amorphous properties stronger than amorphous properties of the material forming the first pixel electrode 3311. For example, in case that ITO is used as the first pixel electrode 3311, the protective layer 3314 may use IGZO, indium tin gallium zinc oxide (ITGZO), and/or ZIO, which have amorphous properties stronger than amorphous properties of ITO. For example, the protective layer 3314 may alleviate crystallization of the first pixel electrode 3311. In case that the first pixel electrode 3311 is crystallized, the protective layer 3314 may act as a partition wall against external air penetration as an amorphous layer so as to protect the reflective layer 3313 disposed below the protective layer 3314.

In other embodiments, a second pixel electrode 3312 may be further disposed below the reflective layer 3313. The second pixel electrode 3312 may be a portion which is directly or electrically connected to the pixel circuit PC and may include a transparent conductive metal oxide or a semitransparent conductive metal oxide. The second pixel electrode 3312 may include at least one selected from ITO, IZO, ZnO, In₂O₃, IGO, and AZO, and the second pixel electrode 3312 and the first pixel electrode 3311 may include the same material so as to simplify the process.

According to an embodiment, the second pixel electrode 3312 may be in contact with the second electrode 324 of the TFT 320 of the pixel circuit PC. The second pixel electrode 3312 may include ITO and may be in ohmic contact with the second electrode 324.

The second pixel electrode 3312 may be applied to the embodiments.

According to other embodiments, the protective layer 3314 may include a transparent conductive metal oxide or a semitransparent conductive metal oxide. For example, the amount of the oxygen component of the protective layer 3314 may be larger than the amount of the oxygen component of the first pixel electrode.

For example, the protective layer 3314 may include ITO and oxygen plasma may be performed on the protective layer 3314 after the ITO layer is formed. Accordingly, the amount of the oxygen component of the protective layer 3314 may be increased. After the protective layer 3314 is formed, the first pixel electrode 3311 may be formed on the protective layer 3314 again by using ITO. The protective layer 3314 including the same transparent conductive metal oxide or semitransparent conductive metal oxide as the first pixel electrode 3311 may act (or function) as a pixel electrode which overcomes the work function difference from the organic layer 333 together with the first pixel electrode 3311.

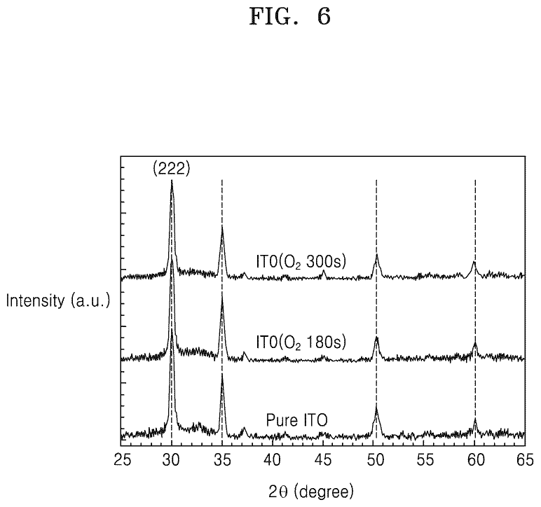

FIG. 6 is a graph showing an X-ray diffraction (XRD) difference of the protective layer 3314 according to an oxygen plasma treatment time in an embodiment in which ITO is used as the protective layer 3314.

The crystallinity increases as the (222) peak increases, which corresponds to the primary crystallographic plane of ITO. However, it may be confirmed from FIG. 6 that the peak in the direction 222 of ITO on which oxygen plasma treatment is performed for 300 seconds is lower than the peak in the direction 222 of ITO on which oxygen plasma treatment is not performed, and thus, the crystallinity may be low. Therefore, the protective layer 3314 may sufficiently protect the reflective layer 3313.

According to other embodiments, the protective layer 3314 may include a transparent conductive metal oxide or a semitransparent conductive metal oxide including a tin (Sn) component. The first pixel electrode 3311 may also include a transparent conductive metal oxide or a semitransparent conductive metal oxide including a tin (Sn) component. According to an embodiment, each of the first pixel electrode 3311 and the protective layer 3314 may include ITO. For example, the amount of the Sn component of the protective layer 3314 may be smaller than the amount of the Sn component of the first pixel electrode 3311.

For example, the protective layer 3314 may include ITO. The ITO layer may be formed with a small amount of the Sn component. After the protective layer 3314 is formed, the first pixel electrode 3311 may be formed on the protective layer 3314 again by using ITO. For example, the amount of the Sn component of the first pixel electrode 3311 may be larger than the amount of the Sn component of the protective layer 3314. The protective layer 3314 including the same transparent conductive metal oxide or a semitransparent conductive metal oxide as the first pixel electrode 3311 may act (or function) as a pixel electrode which overcomes the work function difference from the organic layer 333 together with the first pixel electrode 3311.

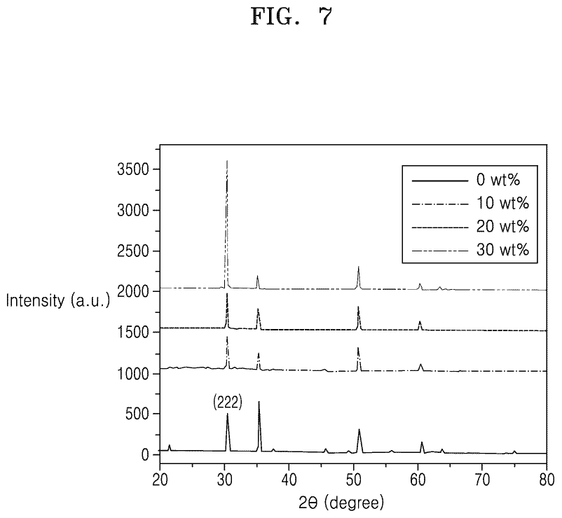

FIG. 7 is a graph showing an XRD difference of the protective layer 3314 according to a concentration ratio of tin (Sn) in an embodiment in which ITO is used as the protective layer 3314.

As described above, the crystallinity increases as the intensity of the (222) peak increases, which corresponds to the primary crystallographic plane of ITO. However, it may be confirmed from FIG. 7 that in case that the concentration ratio of tin (Sn) is about 30 wt %, the intensity of the (222) peak is formed to be high, and thus, the crystallinity increases. Accordingly, it is desirable that the concentration ratio of tin (Sn) in the protective layer 3314 is as low as possible. Therefore, for example, the protective layer 3314 may sufficiently protect the reflective layer 3313.

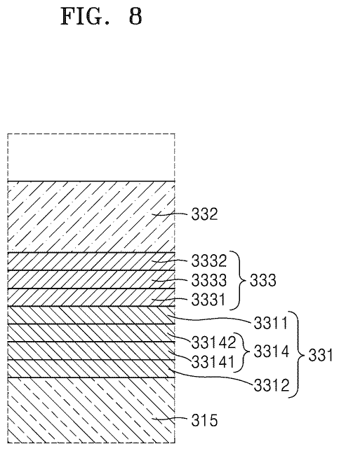

FIG. 8 is a schematic cross-sectional view illustrating region A of FIG. 4 according to another embodiment.

In the embodiment illustrated in FIG. 8, a protective layer 3314 may include a first protective layer 33141 and a second protective layer 33142.

The first protective layer 33141 may be formed on a reflective layer 3313 by using the same material as the material of a first pixel electrode 3311, and the second protective layer 33142 may be formed between the first protective layer 33141 and the first pixel electrode 3311 as an amorphous layer. Amorphous characteristics of the second protective layer 33142 may be relatively higher than amorphous characteristics of the first protective layer 33141. The second protective layer 33142 and the protective layer 3314 used in the embodiments described above may include the same material.

In other embodiments, similar to the first pixel electrode 3311, the first protective layer 33141 may include ITO. For example, the second protective layer 33142 may use IGZO, ITGZO, and/or ZIO, which have amorphous characteristics stronger than amorphous characteristics of ITO.

In other embodiments, the second protective layer 33142 may use a transparent conductive metal oxide or a semitransparent conductive metal oxide having a larger amount of oxygen than the first protective layer 33141 and/or the first pixel electrode 3311, for example, ITO on which oxygen plasma treatment has been performed for a set time.

In other embodiments, the second protective layer 33142 may use a transparent conductive metal oxide or a semitransparent conductive metal oxide having a smaller amount of tin (Sn) than the first protective layer 33141 and/or the first pixel electrode 3311, for example, ITO on having a smaller amount of Sn.

In case that a stacked structure of the first protective layer 33141 and the second protective layer 33142 is used, the reflectivity of the reflective layer 3313 may not be significantly reduced by controlling the thickness of the stacked structure.

For example, in the case of a comparative example in which Ag is formed to a thickness of about 800 Å as the reflective layer 3313 and ITO is formed to a thickness of about 115 Å as the first pixel electrode 3311 and in the case of an example in which Ag is formed to a thickness of about 800 Å as the reflective layer 3313, ITO is formed to a thickness of about 50 Å as the first protective layer 33141, ITGZO is formed to a thickness of about 50 Å as the second protective layer 33142, and ITO is formed to a thickness of about 65 Å as the first pixel electrode 3311, the reflectivities of about 95.8% and about 95.4% are respectively shown even after a curing process is performed on the pixel defining layer. Accordingly, it may be confirmed that almost the same reflectivities are shown.

In other embodiments, the stack of the first pixel electrode 3311 and the protective layer 3314 of the embodiments described above may have a structure in which multiple layers are stacked by repeatedly applying the process. For example, the reflectivity of the reflective layer 3313 may be slightly reduced, but the reflective layer 3313 may be reliably protected from external air and/or external impurity elements. Thus, the reliability of the organic light-emitting diode OLED may be improved.

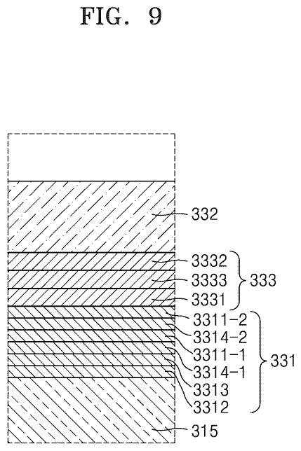

FIG. 9 is a schematic cross-sectional view illustrating region A of FIG. 4 according to other embodiments.

Referring to FIG. 9, a first-1 protective layer 3314-1 may be formed on a reflective layer 3313 and a first-1 pixel electrode 3311-1 may be formed on the first-1 protective layer 3314-1. A first-2 protective layer 3314-2 may be formed on the first-1 pixel electrode 3311-1 and a first-2 pixel electrode 3311-2 may be formed on the first-2 protective layer 3314-2.

The first-1 pixel electrode 3311-1 and the first-2 pixel electrode 3311-2 may include the same material as the material of the first pixel electrodes 3311 of the embodiments described above, and the first-1 protective layer 3314-1 and the first-2 protective layer 3314-2 may include the same material as the material of the protective layer 3314 described above.

By simply repeating the stacking process, the manufacturing process may be further simplified and the degree of protection for the reflective layer 3313 may be further increased.

The display device according to the embodiments described above may minimize the occurrence of defects by protecting the reflective layer from external air or impurity elements in the structure capable of realizing (or implementing) the top emission structure. In case that a black pixel defining layer is used, void defects in the reflective layer may be minimized because unrefined chlorine (Cl) components may be blocked from penetrating into the pinholes by the grain boundary of the first pixel electrode which is crystallized and reacting with the reflective layer. Therefore this may be a more useful structure in the structure which uses the black pixel defining layer to minimize the influence of external light.

A method of manufacturing the display device having the aforementioned structure is described.

Referring to FIG. 4, a circuit substrate including the pixel circuit PC including at least one TFT 320 may be prepared. As described above, the pixel circuit PC may include TFTs using silicon-based semiconductors and/or oxide-based semiconductors.

In other embodiments, the active layer of one of the TFTs included in the pixel circuit PC may include an oxide semiconductor, for example, IGZO. Thus, current leakage in an off state may be reduced.

The pixel electrode 331 electrically connected to the pixel circuit PC may be formed on the planarization layer 315 of the circuit substrate.

The pixel defining layer 316 may be formed on the planarization layer 315 to cover the pixel electrode 331. The opening which exposes a portion of the pixel electrode 331 may be formed through an etching process.

The pixel defining layer 316 may include an organic insulating material and an inorganic insulating material, or may include only an organic insulating material or only an inorganic insulating material.

In other embodiments, the pixel defining layer 316 may include a material including black pigment so as to block (or absorb) external light. The black pixel defining layer 316 including black pigment may require chlorine (Cl) components so as to synthesize a binder. In case that a cardo-type binder is used as the binder, Cl components may be required. The inclusion of Cl— may be inevitable for an epoxy reaction of a cardo-type binder.

The organic layer 333 and the opposite electrode 332 may be stacked above the exposed pixel electrode 331.

In an embodiment, as illustrated in FIG. 5, the first intermediate layer 3331, the emission layer 3333, and the second intermediate layer 3332 may be stacked on the pixel electrode 331 to form the organic layer 333.

The opposite electrode 332 may be formed to cover the organic layer 333. The opposite electrode 332 may be provided (or formed) as a transparent conductive layer or a semitransparent conductive layer. According to an embodiment, the opposite electrode 332 may include a metal thin-film having a low work function and including Li, Ca, LiF/Ca, LiF/Al, Al, Ag, Mg, and any compound thereof. In some embodiments, a transparent conductive oxide (TCO) layer, such as ITO, IZO, ZnO, or In₂O₃, may be further disposed on the metal thin-film.

In some embodiments, the pixel electrode 331 may be stacked to include the first pixel electrode 3311, the reflective layer 3313, and the protective layer 3314.

According to an embodiment, the second pixel electrode 3312 may be formed on the planarization layer 315 for ohmic contact with the pixel circuit PC, and the reflective layer 3313 may be formed on the second pixel electrode 3312. The protective layer 3314 may be formed to cover the reflective layer 3313 and the first pixel electrode 3311 may be formed to cover the protective layer 3314. The organic layer 333 may be deposited on the first pixel electrode 3311.

The second pixel electrode 3312 may be a portion which is directly or electrically connected to the pixel circuit PC and may include a transparent conductive metal oxide or a semitransparent conductive metal oxide. The second pixel electrode 3312 may include at least one selected from ITO, IZO, ZnO, In₂O₃, IGO, and AZO, and the second pixel electrode 3312 and the first pixel electrode 3311 may include the same material so as to simplify the process.

The reflective layer 3313 may include a reflective material including Ag, Mg, Al, Pt, Pd, Au, Ni, Nd, Ir, Cr, or any compound thereof. According to other embodiments, the reflective layer 3313 may include Ag or an Ag compound.

The first pixel electrode 3311 may be provided (or formed) as a transparent conductive layer or a semitransparent conductive layer and may include, for example, at least one selected from ITO, IZO, ZnO, In₂O₃, IGO, and AZO. According to an embodiment, the first pixel electrode 3311 may be in contact with the organic layer 333 and may use ITO. In case that ITO is used, the work function gap of the organic layer 333, e.g., the first intermediate layer 3331, e.g., the HTL, and the first pixel electrode 3311 may be appropriately matched to prevent the driving voltage from increasing.

In other embodiments, the protective layer 3314 may be provided (or formed) as a transparent conductive layer or a semitransparent conductive layer having amorphous properties stronger than amorphous properties of the material forming the first pixel electrode 3311. For example, in case that ITO is used as the first pixel electrode 3311, the protective layer 3314 may use IGZO, ITGZO, and/or ZIO, which have amorphous properties stronger than amorphous properties of ITO.

According to other embodiments, the protective layer 3314 may include a transparent conductive metal oxide or a semitransparent conductive metal oxide. For example, the amount of the oxygen component of the protective layer 3314 may be larger than the amount of the oxygen component of the first pixel electrode.

For example, the protective layer 3314 may include ITO and oxygen plasma may be performed on the protective layer 3314 after the ITO layer is formed. Accordingly, the amount of the oxygen component of the protective layer 3314 may be increased. After the protective layer 3314 is formed, the first pixel electrode 3311 may be formed on the protective layer 3314 again by using ITO. The protective layer 3314 including the same transparent conductive metal oxide or a semitransparent conductive metal oxide as the first pixel electrode 3311 may act as a pixel electrode which overcomes the work function difference from the organic layer 333 together with the first pixel electrode 3311.

According to other embodiments, the protective layer 3314 may include a transparent conductive metal oxide or a semitransparent conductive metal oxide including a tin (Sn) component. The first pixel electrode 3311 may also include a transparent conductive metal oxide or a semitransparent conductive metal oxide including a tin (Sn) component. According to an embodiment, each of the first pixel electrode 3311 and the protective layer 3314 may include ITO. For example, the amount of the Sn component of the protective layer 3314 may be smaller than the amount of the Sn component of the first pixel electrode 3311. For example, the protective layer 3314 may include ITO. The ITO layer may be formed with a small amount of the Sn component. After the protective layer 3314 is formed, the first pixel electrode 3311 may be formed on the protective layer 3314 again by using ITO. For example, the amount of the Sn component of the first pixel electrode 3311 may be larger than the amount of the Sn component of the protective layer 3314.

In other embodiments, as illustrated in FIG. 8, the protective layer 3314 may include the first protective layer 33141 and the second protective layer 33142. The first protective layer 33141 may be formed on the reflective layer 3313 by using the same material as the material of the first pixel electrode 3311, and the second protective layer 33142 may be formed between the first protective layer 33141 and the first pixel electrode 3311 as an amorphous layer. Amorphous characteristics of the second protective layer 33142 may be relatively higher than amorphous characteristics of the first protective layer 33141. The second protective layer 33142 and the protective layer 3314 used in the embodiments described above may include the same material.

In other embodiments, similar to the first pixel electrode 3311, the first protective layer 33141 may include ITO. For example, the second protective layer 33142 may use IGZO, ITGZO, and/or ZIO, which have amorphous characteristics stronger than amorphous characteristics of ITO.

In other embodiments, the second protective layer 33142 may use a transparent conductive metal oxide or a semitransparent conductive metal oxide having a larger amount of oxygen than the first protective layer 33141 and/or the first pixel electrode 3311, for example, ITO on which oxygen plasma treatment has been performed for a set time.

In other embodiments, the second protective layer 33142 may use a transparent conductive metal oxide or a semitransparent conductive metal oxide having a smaller amount of tin (Sn) than the first protective layer 33141 and/or the first pixel electrode 3311, for example, ITO on having a smaller amount of Sn.

In other embodiments, the stack of the first pixel electrode 3311 and the protective layer 3314 of the embodiments described above may have a structure in which multiple layers are stacked by repeatedly applying the process.

For example, referring to FIG. 9, the first-1 protective layer 3314-1 may be formed on the reflective layer 3313 and the first-1 pixel electrode 3311-1 may be formed on the first-1 protective layer 3314-1. The first-2 protective layer 3314-2 may be formed on the first-1 pixel electrode 3311-1 and the first-2 pixel electrode 3311-2 may be formed on the first-2 protective layer 3314-2.

The first-1 pixel electrode 3311-1, the first-2 pixel electrode 3311-2, and the first pixel electrodes 3311 of the embodiments described above may include the same material, and the first-1 protective layer 3314-1, the first-2 protective layer 3314-2, and the protective layer 3314 described above may include the same material.

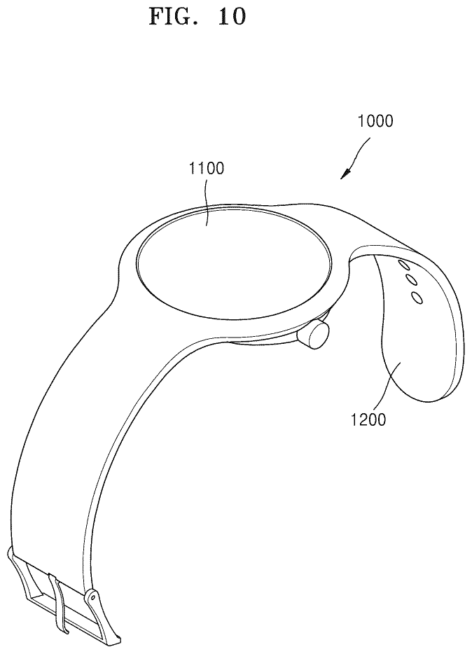

Referring to FIG. 10, the display apparatus may be applied to an electronic device including a smart watch 1000 including a display part 1100 and a strap part 1200.

The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

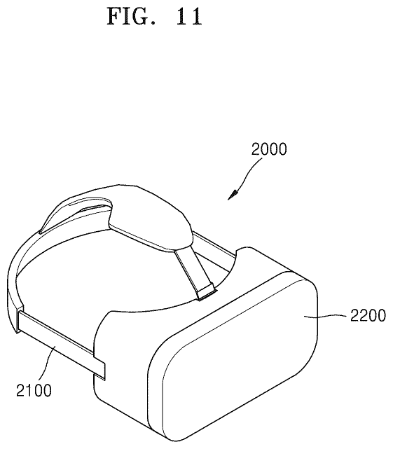

Referring to FIG. 11, the electronic device may include a head mounted display device 2000.

The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure.

For example, the electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

By simply repeating the stacking process, the manufacturing process may be further simplified and the degree of protection for the reflective layer 3313 may be further increased.

According to the embodiments, the occurrence of defects may be minimized by protecting the reflective layer from external air or impurity elements in the structure capable of realizing (or implanting) the top emission structure. In case that a black pixel defining layer is used, void defects in the reflective layer may be minimized because unrefined chlorine (Cl) components may be blocked from penetrating into the pinholes by the grain boundary of the first pixel electrode which is crystallized and reacting with the reflective layer. Therefore, this may be a more useful structure in the structure which uses the black pixel defining layer to minimize the influence of external light, such as an oxide semiconductor.

Each of the embodiments described above may be implemented independently, but it is obvious that the structure of each of the embodiments may be applied in combination to other embodiments.

The disclosure has been described with reference to the embodiments illustrated in the drawings, but this is only an example. It will be understood by those of ordinary skill in the art that various modifications and equivalents may be made thereto. Accordingly, the true technical protection scope of the disclosure should be defined by the technical spirit of the appended claims.

Specific executions described in the embodiments are embodiments, which do not limit the scope of the embodiments in any way. When there is no specific mention such as “essential,” “important,” etc., it may not be a necessary component for the application of the disclosure.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a pixel circuit comprising at least one thin-film transistor;
an organic light-emitting diode electrically connected to the pixel circuit; and
an insulating layer defining a pixel area,
wherein the organic light-emitting diode comprises:
a pixel electrode electrically connected to the pixel circuit;
an opposite electrode opposite at least the pixel electrode; and
an organic layer disposed between at least the pixel electrode and the opposite electrode and comprising at least an emission layer,
the pixel electrode comprises:
a first pixel electrode in contact with the organic layer;
a reflective layer opposite the first pixel electrode and that reflects light from the emission layer; and
a protective layer disposed between the first pixel electrode and the reflective layer and that protects the reflective layer.

2. The display device of claim 1, wherein the protective layer comprises a transparent conductive layer.

3. The display device of claim 2, wherein the transparent conductive layer comprises an amorphous layer.

4. The display device of claim 2, wherein the transparent conductive layer comprises a stack of a first protective layer including a same material as a material of the first pixel electrode and a second protective layer formed as an amorphous layer.

5. The display device of claim 1, wherein each of the first pixel electrode and the protective layer comprises a transparent conductive layer including an oxygen component, and
an amount of the oxygen component of the protective layer is larger than an amount of the oxygen component of the first pixel electrode.

6. The display device of claim 1, wherein
each of the first pixel electrode and the protective layer comprises a transparent conductive layer including a tin component, and
an amount of the tin component of the protective layer is smaller than an amount of the tin component of the first pixel electrode.

7. The display device of claim 1, wherein a stack of the first pixel electrode and the protective layer is stacked in a plurality of layers.

8. The display device of claim 1, further comprising:
a second pixel electrode electrically connected to the pixel circuit to form an ohmic contact,
wherein the reflective layer is disposed between the second pixel electrode and the protective layer.

9. A method of manufacturing a display device, the method comprising:
preparing a circuit substrate comprising a pixel circuit comprising at least one thin-film transistor;
forming, on the circuit substrate, an organic light-emitting diode electrically connected to the pixel circuit; and
forming, on the circuit substrate, an insulating layer defining a pixel area,
wherein the forming of the organic light-emitting diode comprises:
forming a pixel electrode electrically connected to the pixel circuit;
forming, on the pixel electrode, an organic layer comprising at least an emission layer; and
forming an opposite electrode on at least the organic layer,
the forming of the pixel electrode comprises:
forming a reflective layer that reflects light from the emission layer;
forming, on the reflective layer, a protective layer that protects the reflective layer; and
forming, on the protective layer, a first pixel electrode in contact with the organic layer.

10. The method of claim 9, wherein the forming of the protective layer comprises forming a transparent conductive layer.

11. The method of claim 10, wherein the transparent conductive layer comprises an amorphous layer.

12. The method of claim 10, wherein the forming of the transparent conductive layer comprises:
forming a first protective layer including a same material as a material of the first pixel electrode; and
forming, on the first protective layer, a second protective layer formed as an amorphous layer.

13. The method of claim 9, wherein
each of the first pixel electrode and the protective layer comprises a transparent conductive layer including an oxygen component, and
the forming of the protective layer comprises:
forming the transparent conductive layer; and
performing oxygen plasma treatment on at least a portion of the transparent conductive layer.

14. The method of claim 9, wherein
each of the first pixel electrode and the protective layer comprises a transparent conductive layer including a tin component, and
the forming of the protective layer is performed so that an amount of the tin component of the protective layer is smaller than an amount of the tin component of the first pixel electrode.

15. The method of claim 9, wherein
the forming of the protective layer comprises:
forming a first-1 protective layer; and
forming a first-2 protective layer,
the forming of the first pixel electrode comprises:
forming a first-1 pixel electrode between the first-1 protective layer and the first-2 protective layer; and
forming a first-2 pixel electrode on the first-2 protective layer.

16. The method of claim 9, further comprising:
forming a second pixel electrode electrically connected to the pixel circuit to form an ohmic contact,
wherein the forming of the reflective layer comprises forming the reflective layer between the second pixel electrode and the protective layer.

17. An electronic device comprising:
a display device comprising:
a pixel circuit comprising at least one thin-film transistor;
an organic light-emitting diode electrically connected to the pixel circuit; and
an insulating layer defining a pixel area,
wherein the organic light-emitting diode comprises:
a pixel electrode electrically connected to the pixel circuit;
an opposite electrode opposite at least the pixel electrode; and
an organic layer disposed between at least the pixel electrode and the opposite electrode and comprising at least an emission layer,
the pixel electrode comprises:
a first pixel electrode in contact with the organic layer;
a reflective layer opposite the first pixel electrode and that reflects light from the emission layer; and
a protective layer disposed between the first pixel electrode and the reflective layer and that protects the reflective layer.

18. The electronic device of claim 17, wherein the protective layer comprises a transparent conductive layer.

19. The electronic device of claim 17, wherein
each of the first pixel electrode and the protective layer comprises a transparent conductive layer including an oxygen component, and
an amount of the oxygen component of the protective layer is larger than an amount of the oxygen component of the first pixel electrode.

20. The electronic device of claim 17, wherein
each of the first pixel electrode and the protective layer comprises a transparent conductive layer including a tin component, and
an amount of the tin component of the protective layer is smaller than an amount of the tin component of the first pixel electrode.
